(19) United States
(12) Patent Application Publication
(10) Pub. No.: US 2009/0297075 A1
(43) Pub. Date: Dec. 3, 2009

(54) Hydrostatic Slider

(75) Inventor: Takeshi Muneishi, Shiga (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/097,499

(22) PCT Filed: Dec. 15, 2006
(86) PCT No.: PCT/JP2006/325020

§ 371 Date: Jan. 12, 2009

(30) Foreign Application Priority Data
Dec. 15, 2005 (JP) 2005-362396

(51) Int. Cl. F16C 32/06; G01R 27/26

(52) U.S. Cl. 384/12; 324/658

(57) ABSTRACT

A static pressure slider 1 includes a stationary member 2, a movable member 3, and a measuring unit for measuring an actual distance between the stationary member 2 and the movable member 3. Preferably, the measuring unit includes conductive layers 21-24, 31A-34A respectively formed on the stationary member and the movable member 3. The measuring unit may serve to measure a capacitance between guiding surfaces 25-28 and surfaces facing thereto.

### TECHNICAL FIELD

The present invention relates to a static pressure slider configured to move a movable member relative to a stationary member, with a static pressure fluid layer formed of pressurized fluid to be provided between the stationary member and the movable member. Specifically, the present invention relates to a static pressure slider suitable for transferring works in a vacuum chamber.

### RELATED ART

In a semiconductor manufacturing apparatus, a transferring device called “stage” is used for transferring works such as wafers and masks. Such stage includes a guide for guiding the movable member in a predetermined direction. The exemplary guides include a sliding guide, a rolling guide using a plurality of rollers or balls and a static pressure guide using static pressure fluid. The structure of the guide determines the movement accuracy of the movable member of the stage, or the guiding accuracy (e.g. posture accuracy, straightness accuracy) of the stage. In view of the guiding accuracy of the stage, the static pressure guide is considered to have a superiority, and thus stages utilizing static pressure guides are widely used.

Such stage with such static pressure guide is called “static pressure slider”, and includes a stationary member composing a guide and a movable member on which works are placed. In the static pressure slider, a pressurized fluid is supplied to a space between the stationary member and the movable member to form a fluid layer which allows to move the movable member in a predetermined direction without contacting the stationary member. In the static pressure slider, the fluid layer functions as a bearing, and generally has a thickness of 5-10 μm by supplying a pressurized fluid under a pressure of 3-5 atmospheres.

By utilizing the fluid layer as a bearing for guiding the movable member without contact, the static pressure slider is less likely to be affected by flatness or straightness of the stationary member, differently from the stages utilizing other guides (e.g. sliding guide, rolling guide) of contact type. Thus, the static pressure slider shows an excellent guiding accuracy in comparison with other stages utilizing guides of contact type. Further, by reducing the thickness of the fluid layer, the posture of the movable member is further stabilized in the static pressure slider, thereby enhancing the guiding accuracy of the stage.

Meanwhile, the semiconductor manufacturing process includes various steps, as a result, various devices are used in the steps. The stage as one of the devices is used within a chamber (vacuum chamber) under vacuum or a reduced-pressure atmosphere. The exemplary devices used in such vacuum chamber include devices for processing and checking the works by charged particles such as electron beam and ion beam, or by electromagnetic radiation of shorter wavelength such as X-ray: a scanning electron microscope (SEM); an electron beam (EB) recorder; a focus ion beam (FIB) recorder; and an X-ray exposure device.

As described above, in the static pressure slider, a highly pressurized (under 3-5 atmospheres, for example) fluid layer is to be provided between the stationary member and the movable member. When the static pressure slider is used as a stage in a vacuum chamber, it is necessary to reduce the leakage of the fluid into the vacuum chamber. Such static pressure slider is called as “vacuum air slider”, as shown in FIG. 14, for example (refer to Patent document 1 listed below).

The vacuum air slider 9 shown in FIG. 14 includes a stationary member 90 and a movable member 91, and is configured to allow an air to be supplied and discharged at the movable member 91. The movable member 9′ includes a supply portion 92 for supplying a pressurized fluid between the movable member and the stationary member 90, and a discharge portion 93 for discharging the fluid. The supply portion 92 serves to form a fluid layer with a thickness of about 5-10 μm between the stationary member 90 and a movable member 91, and includes a supply path 94 and a throttle 95. The throttle 95 serves to control the amount of supplied fluid, and is provided as an orifice throttle, a surface throttle, or a porous throttle. The discharge portion 93 includes a discharge port 96 and a discharge path 97, and is connected to a non-illustrated pump to discharge the fluid.

As described above, in a static pressure slider such as the vacuum air slider 9, by reducing the thickness of the fluid layer, the posture of the movable member 9 is stabilized, thereby enhancing the guiding accuracy. However, in the vacuum air slider 9, there is a limit to have a relatively high flatness at the stationary member 90 and the movable member 91, and deformation due to own weight of the stationary member 90 is generated. Therefore, if the thickness of the fluid layer is unduly reduced, the movable member 9′ may get into contact with the stationary member 90 when the movable member 9′ moves, as a result, “seizing” is generated. In order to prevent such disadvantage, the fluid layer needs a thickness of not less than a predetermined value, and in the vacuum air slider 9, the thickness of the fluid layer has been limited to not less than about 8 μm.

Then, in order to reduce “seizing”, a vacuum air slider 9′ as shown in FIG. 15 was proposed (refer to Patent document 2 listed below). The illustrated air slider 9′ has a structure similar to the vacuum air slider 9 shown in FIG. 13, and includes a stationary member (guiding bar) 90′ and a movable member 91′. In the vacuum air slider 91, the movable member 91′ includes a labyrinth bulkhead 98′ and a throttle (porous pad) 95′, both form of an abrasion-resistant porous material. Such structure tries to reduce the contact between metal parts of the stationary member 90′ and the movable member 91′, and tries to prevent “seizing”. In the vacuum air slider 9′, the thickness of the fluid layer is set to about 5 μm, so that the posture of the movable member 91′ is stabilized to enhance the guiding accuracy.

In the vacuum air slider 9′ shown in FIG. 15, the thickness of the fluid layer is smaller than that of the vacuum slider 9 shown in FIG. 14. However, the thickness of the fluid layer, or the distance between the stationary member 90′ and the movable member 91′, which is only 5 μm, most affects the amount of the fluid leaking into the vacuum chamber. In order to prevent the pressurized fluid from leaking out of the vacuum air slider 9′, a vacuum pump of the vacuum chamber, or a vacuum pump connected to a discharge path 97′ of the movable member 91′ needs to be driven with a relatively large exhaust velocity. Further, the amount of the pressurized fluid supplied to the vacuum air slider 9′ is still large, which increases the running cost of an apparatus using the vacuum air slider 9′.

As shown in FIGS. 16A-16C, the vacuum air slider is configured to detect the distance between a labyrinth member 98″ supported to a movable member 91″ and a guiding surface 90A″ of a stationary member 90″ with a sensor 99A″ and then to adjust the distance by controlling a distance adjusting mechanism for adjusting the distance, based on the detected result (refer to Patent document 3 listed below). An exemplary sensor 99A″ includes a non-contact displacement gauge such as a capacitance type displacement gauge, an eddy current displacement gauge, and an optical displacement gauge. The distance adjusting mechanism is configured to move the labyrinth member 98″ by using an actuator 99B″ such as a piezoelectric element, a super-magnetostrictive element, and an electromagnet.

Patent Document 1: U.S. Pat. No. 4,749,283

Patent Document 2: JP-A-2-212624

Patent Document 3: JP-A-2002-3495569

### DISCLOSURE OF THE INVENTION

In the vacuum air slider 9″ illustrated in FIGS. 16A-16C, the sensor 99A″ is supported to the movable member 91″ at the side of the movable member 91″, and detects the displacement amount of the labyrinth member 98″. In the other words, the sensor of the vacuum air slider 9″, detects, at a position apart from the labyrinth member 98″, the distance between the guiding surface 90A″ of the stationary member 90′ and an facing surface 98A″ of the labyrinth member 98″ which faces the guiding surface 90A″. With such structure of the vacuum air slider 9″, the actual distance “hr” between the guiding surface 90A″ and the labyrinth member 98″ is not measured, but the displacement amount of the labyrinth member 98″ relative to the guiding surface 90A″ is detected at a position apart from the labyrinth member 98″, which makes it difficult to achieve an accurate measurement. As a result, when the labyrinth member 981 contacts the guiding surface 90A″, the fact is not detected immediately, so that “seizing” is still likely to be generated.

An object of the present invention is to provide a static pressure slider, in which “seizing” at the stationary member caused by the contact of the movable member, as well as leaking of the pressurized fluid from the static pressure slider are reduced. Another object of the present invention is to enhance the posture stability of the movable member by reducing the thickness of the fluid layer, thereby reducing the supply amount of pressurized fluid, and thus reducing the running cost.

According to one of the present invention, a static pressure slider includes a stationary member including a guiding surface, and a movable member configured to be movable relative to the stationary member along the guiding surface under a condition that a static pressure fluid layer formed of a pressurized fluid is provided between the stationary member and the guide surface, wherein the static pressure slider further comprises a measuring unit adapted for measuring an actual distance between the guiding surface and a facing surface of the movable member which faces the guiding surface and is located at an end portion of the movable member.

The measuring unit may be adapted for measuring a capacitance between the guiding surface and the facing surface. The measuring unit may include a first conductive layer formed on the guiding surface and a second conductive layer formed on the facing surface. The first and second conductive layers may be used for measuring the capacitance therebetween

Preferably, each of the first and second conductive layers has a smooth surface with the maximum height Rz of not more than 1 μm. Each of the first and second conductive layers may be made of a metal or a single crystal. Each of the first and second conductive layers may be formed into thick layers using a metal. Each of the first and second conductive layers may have a thickness of not less than 0.1 μm and not more than 0.1 mm. Each of the first and second conductive layers may be made of a non-magnetic material.

The movable member includes a main body and a displacement body, the displacement body configured to be displaceable relative to the main body in a direction perpendicular to the moving direction of the movable member, the displacement body having an end surface including the facing surface of the movable member. In this case, the static pressure slider according to one of the present invention further includes a controller configured to control the position of the displacement body in order to adjust the distance between the guiding surface and the facing surface based on the measurement result obtained by using the measuring unit.

The main body may includes a discharge channel for discharging the pressurized fluid to the outside/and the displacement body may be positioned.

The movable member further may include a piezoelectric element for moving the displacement body. The piezoelectric element is controlled to expand and contract by the controller.

The displacement body is preferably supported by the main body while the displacement body is pressed in a direction apart from the guiding surface. The static pressure slider may further include a sealing member for sealing a gap between the main body and the displacement body.

The displacement body may be provided with a plurality of piezoelectric elements aligned in a direction perpendicular to the moving direction of the movable member. The displacement body may include an elastically deformable member to which the piezoelectric elements is fixed.

The deformable member may include a plurality of thick portions to which the piezoelectric elements are fixed, and a plurality of thin portions positioned between the adjacent thick portions.

Preferably, the displacement body further includes a protect resin member surrounding the piezoelectric elements.

Preferably, at least one of the first and second conductive layers includes a plurality of individual electrodes in a region corresponding to the piezoelectric elements.

In the static pressure slider according to one of the present invention, while the movable member moves relative to the stationary member, the actual distance between the guiding surface and the facing surface is measured by using the measuring unit, thereby, the distance between the stationary member and the movable member is accurately measured. Thus, the static pressure slider according to one of the present invention remarkably improve the measurement accuracy of the distance between the stationary member and the movable member, comparing with, for example, the method in which the distance between the stationary member and the movable member is calculated based on a measurement result obtained through measuring the distance at a portion other than the portion between the guiding surface and the facing surface by measuring the displacement sensor.

Displacing the movable member (the displacement body) according to the accurately measured distance makes it possible to properly keep the distance between the stationary member and the movable member, whereby the movable member may be less likely to get too close to the stationary member, which can prevent the movable member from getting into contact with the stationary member. As a result, “seizing” due to the contact of the movable member to the stationary member can be also prevented, thereby reducing the damages of the stationary member and the movable member. Especially, Pressing the displacement body in the direction away from the stationary member enables the displacement body to be responsively retracted from the stationary member by using the actuator for displacing the displacement body. Therefore, the static pressure slider according to one of the present invention can reduce “seizing” even if the distance between the stationary member and the movable member is set to a relatively small value, and thus the thickness of the fluid layer which is to be provided between the stationary member and the movable member can be smaller.

As a result, the static pressure slider according to one of the present invention can improve the posture accuracy of the movable member relative to the stationary member, and constantly keep the distance between the stationary member and the movable member relatively small, thereby reducing the amount of the pressurized fluid to be supplied between the stationary member and the movable member. Even if the movable member gets into contact with the stationary member, the capacitance immediately drops to zero. Therefore, the contact of the movable member to the stationary member can be immediately detected based on the capacitance measured by the measuring unit, and the problem due to the contact can be held to the minimum. Further, since the displacement body pressed in the direction apart from the stationary members the displacement body can responsively retracted from the stationary member, and the problem due to the contact can be held to the minimum.

Since the distance between the stationary member and the movable member can be constantly kept to be relatively small, leaking the pressurized fluid to be provided between the stationary member and the movable member is reduced, whereby, the vacuum pump for discharging the pressurized fluid from the static pressure slider can be driven by a lower exhaust velocity and a lower electrical power. As a result, the cost for discharging the pressurized fluid can be reduced. Further, since reducing the leakage of the pressurized fluid out of the static pressure slider can reduce the loss of vacuum in the vacuum chamber (not shown), the exhaust velocity and electrical power necessary for maintaining the degree of vacuum in the vacuum chamber can be smaller. Thus, the running cost of the static pressure slider is reduced also in this point.

Forming the first conductive layer and the second conductive layer constituting the measuring unit to have smooth surfaces can reduce the possibility that the second conductive layer contacts the first conductive layer, in other words, the possibility that the movable member contacts the stationary member, can reduce the number of the holes on the surfaces of the stationary member and the movable member, can measure the capacitance between the first conductive layer and the second conductive layer accurately, and can more reliably prevent the pressurized fluid from leaking outside, in comparison with the case in which the first conductive layer and the second conductive layer have rough surfaces. That is, the distance between the stationary member and the movable member, required to prevent “seizing” is set to be smaller, and thus the thickness of the fluid layer to be provided between the stationary member and the movable member is set to be further smaller.

Further, in the case that the static pressure slider according to one of the present invention is used in devices utilizing charged particles such as an scanning electron microscope (SEM), an electron beam (EB) recorder, and a focus ion beam (FIB) recorder, forming the first conductive layer and the second conductive layer to be non-magnetic prevents such devices from adverse effect of the first conductive layer and the second conductive layer. In this way, the static pressure slider according to one of the present invention can be used without problem in the devices utilizing charged particles.

Still further, providing the sealing member between the main body and the displacement body can prevent the pressurized fluid for forming the fluid layer from leaking out of between the main body and the displacement body. Especially when the displacement body is displaced relative to the main body, it is advantageous to reduce the leakage of the pressurized fluid by the sealing member.

The displacement body with a plurality of piezoelectric elements makes it possible to adjust the distance between the stationary member and the movable member by individual expansion and contraction of the piezoelectric elements. For example, when the piezoelectric elements are fixed to an elastically deformable member, deforming the deformable member by expanding and contracting the piezoelectric makes it possible to delicately adjust the distance between the displacement body (the movable member) and the stationary member.

### BRIEF DESCRIPTION OF THE DRAWINGS

FIG. 1 is an overall perspective view illustrating a vacuum air slider according to a first embodiment of the present invention.

FIG. 2 is a sectional view taken along lines II-II of FIG. 1.

FIG. 3 is a sectional view taken along lines III-III of FIG. 1.

FIG. 4 is a partly exploded perspective view of a movable member of the vacuum air slider in FIG. 1.

FIG. 5 is a sectional view taken along lines V-V of FIG. 4.

FIG. 6 is a sectional view taken along lines VI-VI of FIG. 3.

FIG. 7 is a sectional view taken along lines VII-VI of FIG. 3.

FIG. 8 is a sectional view enlarging the principal portions of FIG. 6.

FIG. 9 is a block diagram of the vacuum air slider of FIG. 1.

FIG. 10 is an overall perspective view illustrating a vacuum air slider according to a second embodiment of the present invention.

FIG. 11 is a sectional view taken along lines XI-XI of FIG. 10.

FIG. 12 is a sectional view taken along lines XII-XII of FIG. 11.

FIG. 13 is a sectional view enlarging the principal portions of FIG. 11.

FIG. 14 is a sectional view illustrating an example of a conventional static pressure slider.

FIG. 15 is a sectional view illustrating another example of a conventional static pressure slider.

FIG. 16A is a sectional view illustrating still another example of a conventional static pressure slider, FIG. 16B is a bottom view of FIG. 16A, and FIG. 16C is a sectional view taken along lines XVIC-XVIC of FIG. 16B.

### NUMERICAL REFERENCE

1, 1′ vacuum air slider (static pressure slider)
2 stationary member
21-24 guiding surface
25-28, 25′-28′ first conductive layer (of stationary member)
25A′-28A′ individual electrode
3, 3 movable member
30 main body (movable body)
31-34, 31′-34′ displacement body
31B′-34B′ deformable member (of displacement body)
31Ba′-34Ba′ thick portion (of deformable member)
31Bb′-34Bb′ thin portion (of deformable member)
31C′-34C′ piezoelectric element (of displacement body)
31D′-34D′ protect resin member (of displacement body)
31A-34A second conductive layer (of displacement body)
31b-34b bottom end surface (of displacement body)
61 piezoelectric element
63 packing (sealing member)
70 measuring portion (measuring unit)
72 controlling portion (controlling unit)

Static pressure sliders according to first and second embodiments of the present invention are described with reference to the drawings, by taking a vacuum air slider as an example.

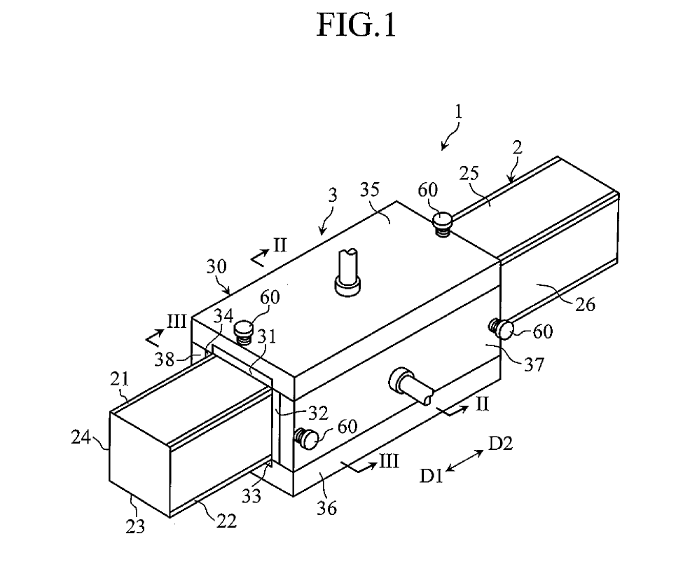

First, a vacuum air slider according to a first embodiment of the present invention is described with reference to FIGS. 1-9.

The vacuum air slider 1 shown in FIG. 1, is an exemplary static pressure slider according to one of the present invention, and is used for transferring works in a vacuum chamber. The vacuum air slider 1 includes a stationary member 2 and a movable member 3. The movable member 3 is configured to be able to move relative to the stationary member 2 in directions D1, D2, with a fluid layer formed of a pressurized fluid interposed between the stationary and movable members 2 and 3.

As shown in FIGS. 1-3, the stationary member 2 serves to guide the movable member 3, and is formed into a rectangular column with four guiding surfaces 21, 22, 23/and 24. The stationary member 2 is made of a ceramics material mainly containing alumina or silicon carbide, for example.

The guiding surfaces 21-24 define the movement path of the movable member 3. Each of the guiding surfaces 21-24 extends in the directions D1, D2 shown in FIG. 1 and is formed into a smooth surface, for example. The guiding surfaces 21-24 are provided with first conductive layers 25, 26, 27, 28, respectively. As specifically described below, the first conductive layers 25-28 are used for measuring a distance between end portions of the movable member 3 (or displacement bodies 31-35 which are described below) and the stationary member 2, and are formed into a strip-shape extending in the axial direction of the stationary member 2 to cover the whole area of the guiding surfaces 21-24.

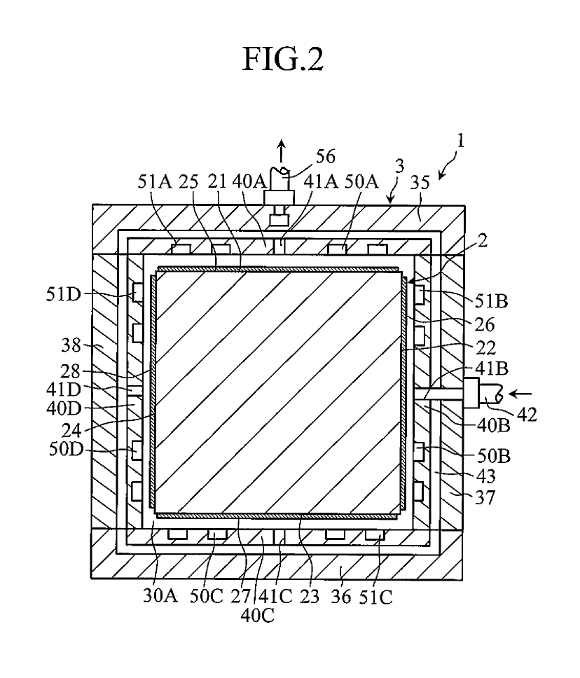

As shown in FIG. 1, the movable member 3 is operative to move along the guiding surfaces 21-24 of the stationary member 2 in the directions D1, D2, while surrounding the stationary member 2, and as shown in FIGS. 2-4, includes a main body 30 and displacement bodies 31, 32, 33 and 34.

The main body 30 includes four boards 35, 36, 37 and 38, and is formed into a tube including a hollow 30A having a rectangular section by connecting these boards 35-38 so that the main body 30 surrounds the stationary member 2.

Each of the boards 35-38 is rectangular as seen in plan view. The boards 35 and 36 are horizontally positioned and have a relatively large size, while the boards 37 and 38 are vertically positioned and have a relative small size. The boards 35-38 respectively include air pads 40A, 40B, 40C and 40D, circular discharge channels 50A, SOB, 50C, 50D, 51A, 51B, 51C and 51D, and linear discharge channels 52A, 52B, 52C and 52D. Similarly to the stationary member 2, the boards 35-38 are made of a ceramics material mainly containing alumina or silicon carbide, for example. Preferably, the surfaces of the boards 35-38 to be connected to each other are provided with vacuum grease, whereby the leakage of a fluid from the connected surfaces can be prevented.

The air pads 40A-40D serve as throttles for controlling the feed rate of a supplied fluid and are provided as orifice throttles, surface throttles, or porous throttles. As well shown in FIG. 2, the air pads 40A-40D respectively include supply tubes 41A, 41B, 41C, 41D. These supply tubes 41A-41D are connected to a circular supply passage 43 which is connected to a supply pipe 42 provided at the vertical board 37. With such structure, a pressurized fluid is supplied from the air pads 40A-40D, through the supply pipe 42, the circular supply passage 43 and the supply tubes 41A-41D.

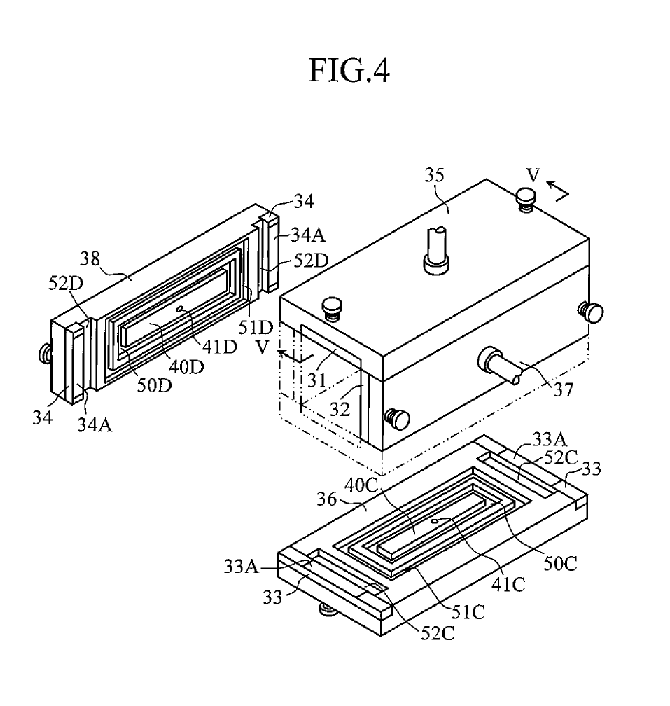

The circular discharge channels 50A-50D and 51A-51D serve to collect the pressurized fluid supplied from the air pads 40A-40D, and as may be seen from FIGS. 2 and 4, the circular discharge channels 50A-50D and 51A-51D are formed to surround the air pads 40A-40D. These circular discharge channels 50A-50D and 51A-51D, though not shown in drawings, are connected to the outside of a vacuum chamber (not shown in drawings) through a discharge pipe so that the pressurized fluid is discharged out of the vacuum chamber.

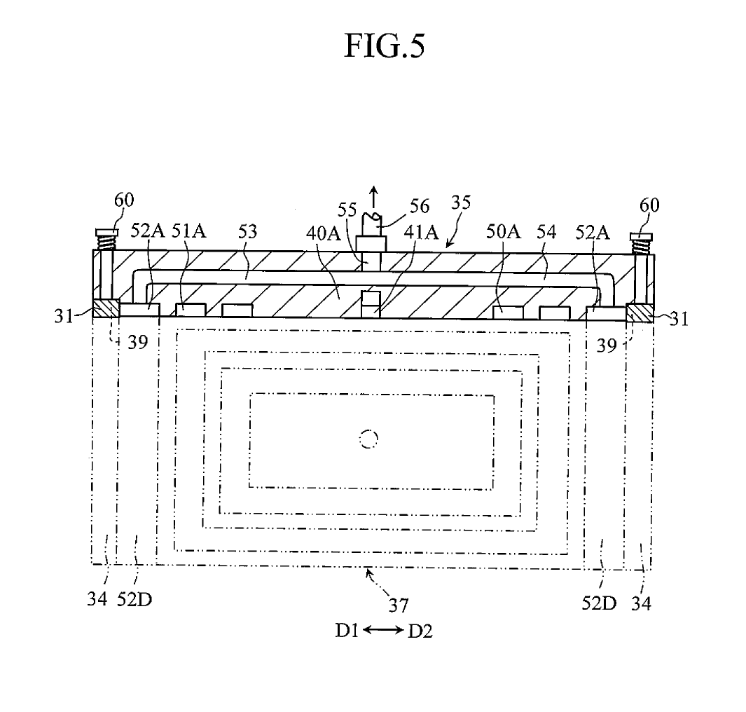

As may be seen from FIGS. 4 and 5, the linear discharge channels 52A-52D are connected to each other by connecting the boards 35-38, and serve as a circular discharge channel of the main body 30 as a whole. As well shown in FIG. 4, these linear discharge channels 52A-52D are provided at the both end portions of the boards 35-38 in the longitudinal directions D1 and D2, and extend in the width direction of the boards. The linear discharge channels 52B and 52D of the vertical boards 37 and 38 are formed up to the side edges of the boards, and are open in its width direction. On the other hand, the linear discharge channels 52A and 52C of the horizontal boards 35 and 36 are formed at portions except the side edges of the boards, and are closed in its width direction. As shown in FIG. 5, the linear discharge channel 52A of the horizontal board 35 is connected to discharge passages 53 and 54. These discharge passages 53 and 54 are connected to a vacuum pump (not shown in drawings) provided outside of the vacuum chamber, via a common discharge passage 55 and a discharge pipe 56. With such structure, the pressurized fluid is discharge out of the vacuum chamber, from the linear discharge channels 52A-52D through the discharge passages 53 and 54, the common discharge passage 55 and the discharge pipe 56 by driving the vacuum pump.

As shown in FIGS. 1, 3 and 4, the displacement bodies 31-34 serve to keep distances between the end portions of the movable member 3 and the stationary member 2 to be smaller, while preventing the movable member 3 from coming into contact with the stationary member 2, and the displacement bodies 31-34 are formed into a bar-shape with rectangular section. These displacement bodies 31-34 are fixed to the end portions of the boards 35-38 in the directions D1 and D2 using bolts 60, and are displaceable by actuators 61 in the thickness direction of the boards 35-38.

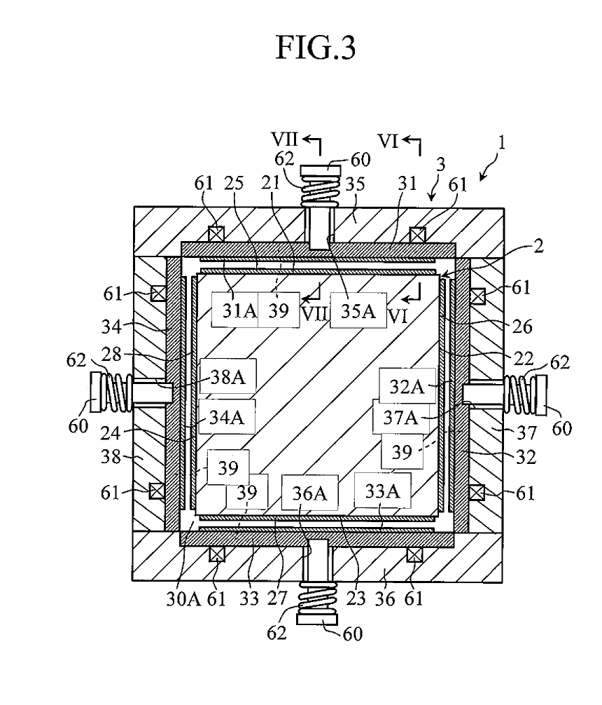

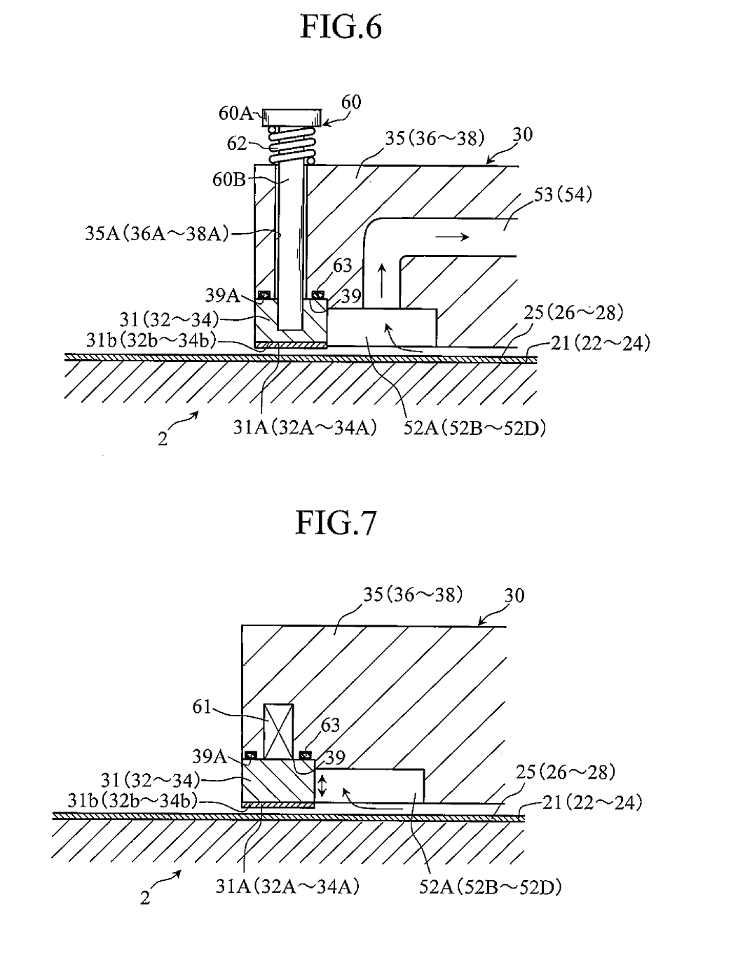

As shown in FIGS. 3 and 5-7, the displacement bodies 31-34 are accommodated in recesses 39 formed at the end portions of the boards 35-38, adjacent to the linear discharge channels 52A-52D, while being fixed to the boards 35-38 by the bolts 60. In this state, as shown in FIGS. 6 and 7, the displacement bodies 31-34 positioned adjacent to the linear discharge channels 52A-52D protrude beyond the main body 30 of the movable member 3 slightly (by about 1-10 μm), and include bottom end surfaces 31b, 32b, 33b and 34b facing substantially parallel to the guiding surfaces 21-24 (the surfaces of the first conductive layers 25-28) of the stationary member 2, substantially parallel thereto. With such structure of the displacement bodies 31-34 protruding beyond the main body 30 of the movable member 3, the leakage of the pressurized fluid from the movable member 3 is reduced, and the pressurized fluid is properly guided to the linear discharge channels 52A-52D. If the linear discharge channels 52A-52D are positioned at the middle portion of the main body 30 of the movable member 3, the displacement bodies 31-34 may be also positioned in the vicinity of the linear discharge channels 52A-52D, preferably positioned on a side of the end portions adjacent to the linear discharge channels 52A-52D.

Each of the bolts 60 includes a head 60A, a coil spring 62 positioned between the head and each of the boards 35-38, and a screw 60B inserted in each of through holes 35A, 36A, 37A and 38A of the boards 35-38. The coil spring 62 is compressed from the natural state. Each of the through holes 35A-38A has a diameter larger than the screw 60B of the bolt 60. Thus, the displacement bodies 31-34 are pressed toward the head 60A due to the elastic force of the coil spring 62, and are displaceable in the thickness direction of the boards 35-38.

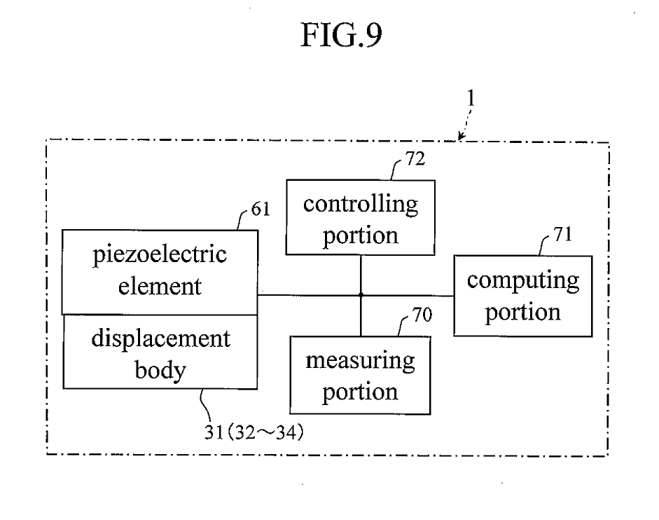

As shown in FIGS. 3 and 7, the displacement bodies 31-34 are displaced in the thickness direction of the boards 35-38 by the actuators 61 provided at the boards 35-38. Two actuators 61 are provided for each of the displacement bodies 31-34. These actuators 61 apply loads to each of the displacement bodies 31-34 at both of the end portions in the longitudinal direction. The actuators 61 include piezoelectric elements, and by expanding and contracting under control of a controller 72 (see FIG. 9) which is described below, apply loads to the displacement bodies 31-34 so that the displacement bodies 31-34 are displaced relative to the boards 35-38.

The actuators 61 may include various known elements such as super-magnetostrictive elements, and electromagnets, other than piezoelectric elements.

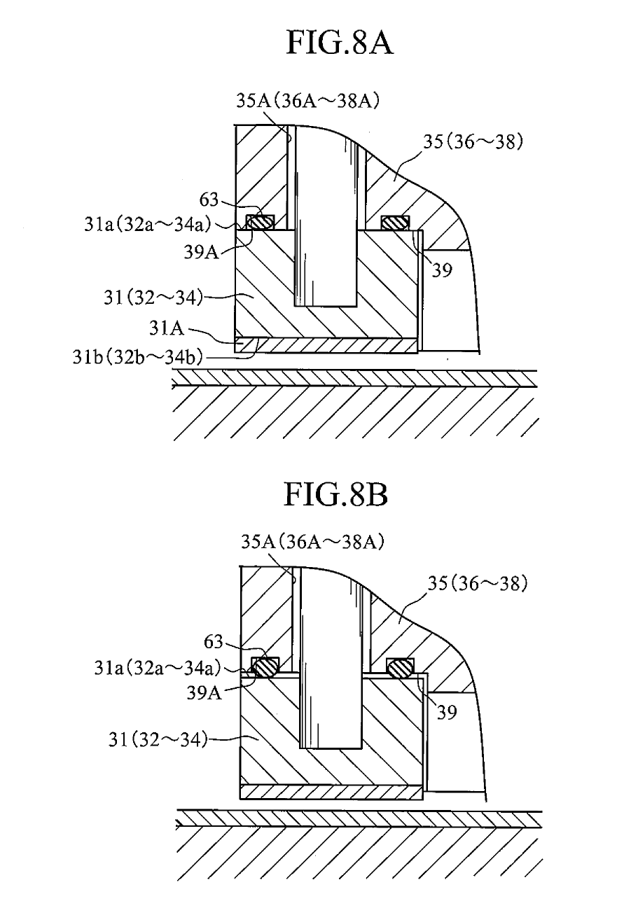

As shown in FIGS. 6-8, packings 63 are provided as sealing members between the displacement bodies 31-34 and the main body 30. Though not shown in drawings specifically, each of the packings 63 is rectangular as seen in plan view, and has a circular section. The packings 63 are made of an elastic material such as rubber, and are accommodated in circular grooves 39A formed in the recesses 39 of the boards 35-38. The circular grooves 39A face top end surfaces 31a, 32a, 33a and 34a of the displacement bodies 31-34 and extend along edges of the top end surfaces 31a-34a of the displacement bodies 31-34. The packings 63 accommodated in the circular grooves 39A are positioned between the boards 35-38 (the circular grooves 39A) and the top end surfaces 31a-34a of the displacement bodies 31-34 in a contacting manner. In this state, the packings 63 surround the edges of the through holes 35A-38A of the boards 35-38. With such structure, as shown in FIGS. 8A and 8B, when the displacement bodies 31-34 are displaced, the packings 63 expand and contract by their elasticity according to the displacement of the displacement bodies 31-34, thereby sealing gaps generated between the boards 35-38 and the displacement bodies 31-34. As a result, the pressurized fluid can be prevented from leaking outside of the vacuum air slider 1 through the gaps between the boards 35-38 and the top end surfaces 31a-34a of the displacement bodies 31-34. Further, the pressurized fluid can be also prevented from leaking outside of the vacuum air slider 1 via the through holes 35A-38A of the boards 35-38.

Of course, the sealing member may include an elastic material other than the rectangular packings 63.

As shown in FIGS. 3, 4, 6 and 7, the bottom end surfaces 31b, 32b, 33b and 34b of the displacement bodies 31-34 are respectively provided with second conductive layers 31A, 32A, 33A and 34A facing the first conductive layers 25-28 of the stationary member 2. The second conductive layers 31A-34A are used, together with the first conductive layers 25-28, for measuring distances between the end portions of the movable member 3 and the stationary member 2, and compose a measuring unit 70 (see FIG. 9) which is described below. Each of the second conductive layers 31A-34A is rectangular as seen in plan view. Each of the second conductive layers 31A-34A has a length the same as the width of the first conductive layers 25-28 of the stationary member 2, and a width the same as the width of the displacement bodies 31-34.

The first conductive layers 25-28 and the second conductive layers 31A-34A of the stationary member 2 and the displacement bodies 31-34 preferably have smooth surfaces with a surface roughness where the maximum height Rz is not more than 1 μm, for example. When the first conductive layers 25-28 and the second conductive layers 31A-34A have smooth surfaces, comparing to the case in which the first conductive layers 25-28 and the second conductive layers 31A-34A have rough surfaces, the second conductive layers 31A-34A are more likely to be prevented from getting into contact with the first conductive layers 25-28, or, the end portions of the movable member 3 (the displacement bodies 31-34) are more likely to be prevented from getting into contact with the stationary member 2. Even if the displacement bodies 31-34 come into contact with the stationary member 2, the fact of the contact is soon detected. Further, since the distances between the stationary member 2 and the displacement bodies 31-34 are kept to be uniform, the pressurized fluid can be prevented from leaking outside. In this way, the distances between the stationary member 2 and the movable member 3 for reducing “seizing” can be set to be smaller, and thus the thickness of the fluid layer between the stationary member 2 and the movable member 3 can be set to be smaller.

To have the smooth surfaces, the first conductive layers 25-28 and the second conductive layers 31A-34A may be grinded, or may be formed of a single crystal. Further, the first conductive layers 25-28 and the second conductive layers 31A-34A may be formed by metal to have a relatively large thickness, in order to offset the surface irregularities and holes on the guiding surfaces 21-24 of the stationary member 2 and the bottom end surfaces 31b-34b of the displacement bodies 31-34, so that the stationary member 2 and the displacement bodies 31-34 have smooth surfaces. For example, when the stationary member 2 and the displacement bodies 31-34 are made of a ceramics material, the surface roughness after grinding process has the maximum height Rz of a couple of micrometers to tens of micrometers. In order to efficiently offset the surface irregularities and holes, the thickness of the first conductive layers 25-28 and the second conductive layers 31A-34A may be set to not less than 0.1 μm and not more than 0.1 mm. Here, the surface roughness (i.e. maximum height Rz, arithmetic mean roughness Ra) was measured based on JIS B0601-2001 (conforming to ISO 24287-1997).

Further, the first conductive layers 25-28 and the second conductive layers 31A-34A may be formed as rigid film in order to reduce “seizing” caused by the contact of the layers. Reducing “seizing” caused by the contact of the first conductive layers 25-28 and the second conductive layers 31A-34A allows the thickness of the fluid layer provided between the stationary member 2 and the movable member 3 to be smaller.

The hardness of the first conductive layers 25-28 and the second conductive layers 31A-34A is preferably set to not less than 1200 in Vickers hardness Hv. The rigid film (the conductive layers 25-28, 31A-34A) with such hardness may be made of TiN, TiC, cermet, AlTiC, or WC. Here, the Vickers hardness Hv was measured based on JIS R1610-2003 (conforming to ISO 14705-2000).

Still further, the first conductive layers 25-28 and the second conductive layers 31A-34A may be preferably formed to be non-magnetic. In the case that the vacuum air slider 1 is used in devices utilizing charged particles such as an scanning electron microscope (SEM), an electron beam (EB) recorder, and a focus ion beam (FIB) recorder, forming the first conductive layers 25-28 and the second conductive layers 31A-34A to be non-magnetic prevent the charged particle control in such devices from adverse effect of the first conductive layers 25-28 and the second conductive layers 31A-34A. In this way, the vacuum air slider 1 according to one of the present invention can be used without problem in the devices utilizing charged particles.

As shown in FIG. 9, the vacuum air slider 1 further includes a measuring portion 70, a computing portion 71, and a controlling portion 72, in addition to the stationary member 2 and the movable member 3.

The measuring portion 70 is composed of the first conductive layers 25-28 and the second conductive layers 31A-34A of the stationary member 2 and the movable member 3, and of an AC power supply (not shown) for applying an electric potential difference across the first conductive layers 25-28 and the second conductive layers 31A-34A. The AC power supply (not shown) of the measuring portion 70 applies a high-frequency voltage of 500 kHz, 5V across the first conductive layers 25-28 and the second conductive layers 31A-34A, while measuring the capacitance between the first conductive layers 25-28 and the second conductive layers 31A-34A. The capacitance between the first conductive layers 25-28 and the second conductive layers 31A-34A correlates with the distances between the first conductive layers 25-28 and the second conductive layers 31A-34A. Thus, by measuring the capacitance between the first conductive layers 25-28 and the second conductive layers 31A-34A, it is possible to figure out the distances between the first conductive layers 25-28 and the second conductive layers 31A-34A, or the distances between the bottom end surfaces 31b-34b of the displacement bodies 31-34 and the guiding surfaces 21-24 of the stationary member 2.

The computing portion 71 calculates the amount of displacement of the displacement bodies 31-34, based on the capacitance measured by the measuring portion 70. Specifically, if the distances between the first conductive layers 25-28 and the second conductive layers 31A-34A (or the distances between the bottom end surfaces 31b-34b of the displacement bodies 31-34 and the guiding surfaces 21-24 of the stationary member 2) deviates from the reference value, the displacement amount is calculated according to the deviating value. More specifically, the computing portion 71 calculates the control input to be inputted to the actuators (piezoelectric element) 61, based on the displacement amount (deviating value) that is necessary for correcting the distances, between the first conductive layers 25-28 and the second conductive layers 31A-34A, to be the reference value. For example, when piezoelectric elements are used for the actuators 61 for moving the displacement bodies 31-34, the computing portion 71 calculates the voltage value to be applied to the piezoelectric elements for expanding and contracting (deforming) the piezoelectric elements, according to the displacement amount.

The computing portion 71 may be omitted by providing the measuring portion 70 with the function of the computing portion 71.

The controlling portion 72 displaces the displacement bodies 31-34 according to the control input calculated by the computing portion 71. For example, when piezoelectric elements are used for the actuators 61, controlled voltage is applied to the piezoelectric elements for expanding and contracting the piezoelectric elements, thereby displacing the displacement elements 31-34.

The above-described computing portion 71 and the controlling portion 72 may include CPU, RAM, and ROM, wherein the program stored in the ROM is used in the RAM while executed by the CPU. The computing portion 71 and the controlling portion 72 may be individually provided for each of the displacement bodies 31-34, or only one set of the computing portion 71 and the controlling portion 72 may be provided for the whole displacement bodies 31-34. Further, the computing portion 71 may be individually provided for each of the displacement bodies 31-34 and only one controlling portion 72 may be provided for the whole displacement bodies 31-34. The computing portion 71 and the controlling portion 72 may be provided separately from the vacuum air slider 1, not within the vacuum air slider 1. For example, the displacement bodies 31-34 of the vacuum air slider 1 may be controlled by a computing portion and a controlling portion of a device in which the vacuum air slider 1 is incorporated.

Next, the operation of the vacuum air slider 1 is described. In the following description, piezoelectric elements are used as the actuators for displacing the displacement bodies 31-34.

In the vacuum air slider 1, the movable member 3 is moved relative to the stationary member 2 by, for example, a non-illustrated actuator at the time when the fluid layer is provided between the movable member 3 and the stationary member 2.

The fluid layer is provided using a non-illustrated pump, by supplying a pressurized fluid from the air pads 40A-40D, through the supply pipe 42, the circular supply passage 43, and the supply tubes 41A-41D. In turn, the pressurized fluid is discharged out of the vacuum chamber (not shown in drawings), through the circular discharge channels 50A-50D and 51A-51D formed at the boards 35-38 and a non-illustrated discharge pipe. Some of the pressurized fluid which are not discharged from the circular discharge channels 50A-50D and 51A-51D are discharged from another circular discharge channel formed by the linear discharge channels 52A-52D formed at the boards 35-38. The pressurized fluid guided to the circular discharge channel (composed of the linear discharge channels 52A-52D) is sucked by the vacuum pump (not shown in drawings) provided outside of the vacuum chamber and discharge out thereof, through the discharge passages 53 and 54, the common discharge passage 55 and the discharge pipe 56.

In the measuring portion 70, a capacitance between the first conductive layers 25-28 of the stationary member 2 and the second conductive layers 31A-34A of the movable member 3 is directly measured to figure out the actual distances between the stationary member 2 and the movable member 3.

In the computing portion 71, based on the capacitance measured by using the measuring portion 70, deviations of the distances between first conductive layers 25-28 and the second conductive layers 31A-34A (or between the bottom end surfaces 31b-34b of the displacement bodies 31-34 and the guiding surfaces 21-24 of the stationary member 2), from the reference value is calculated, and then the control input is calculated according to the deviating values. The calculation result is utilized by the controlling portion 72 as a displacement amount of the displacement bodies 31-34. In other words, the computing portion 71 calculates the control input as a voltage value, and the controlling portion 72 controls the AC power supply (not shown in drawings) of the measuring portion 70 to apply the computed voltage value for expanding and contracting the piezoelectric elements 61.

For example, when the distances between the first conductive layers 25-28 and the second conductive layers 31A-34A are smaller than the reference value, or the displacement bodies 31-34 (the end portions of the movable member 3) get too close to the stationary member 2, the voltage value applied to the piezoelectric elements 61 is reduced for contraction of the piezoelectric elements 61 so that the displacement bodies 31-34 are displaced apart from the stationary member 2. On the other hand, when the distances between the first conductive layers 25-28 and the second conductive layers 31A-34A are larger than the reference value, or the displacement bodies 31-34 (the end portions of the movable member 3) get too apart from the stationary member 2, the voltage value applied to the piezoelectric elements 61 is increased for expansion of the piezoelectric elements 61 so that the displacement bodies 31-34 are displaced toward the stationary member 2.

Since the vacuum air slider 1 is configured to be used for making it possible to directly measure the actual distances between the stationary member 2 and the end portions of the movable member 3 (the displacement bodies 31-34) at the facing portion of these members, the distances between the stationary member 2 and the end portions of the movable member 3 (the displacement bodies 31-34) is accurately measured. In this way, the measurement accuracy is remarkably improved, comparing with a method in which the distances between the stationary member 2 and the end portions of the movable member 3 (the displacement bodies 31-34) is calculated based on the measured result by measuring the distances at a portion other than the facing portion of the members.

By displacing the end portions of the movable member 3 (the displacement bodies 31-34) according to the accurately measured distances, the distances between the stationary member 2 and the movable member 3 can be kept very small, and the movable member 3 can be prevented from getting too close to the stationary member 2. Since the movable member 3 can be prevented from getting into contact with the stationary member 2, “seizing” due to the contact of the movable member 3 to the stationary member 2 can be also prevented. Especially, Supporting the displacement bodies 31-34 pressed in the direction away from the stationary member 2 enables the displacement bodies 31-34 to be responsively retracted from the stationary member 2 when the piezoelectric elements 61 contracts. Therefore, the distances between the stationary member 2 and the movable member 3, required to prevent “seizing” can be smaller, and thus the thickness of the fluid layer to be provided between the stationary member 2 and the movable member 3 can also be smaller. As a result, in the vacuum air slider 1, the posture stability of the movable member 3 relative to the stationary member 2 can be enhanced, and the amount of the pressurized fluid to be supplied between the stationary member 2 and the movable member 3 can be reduced. Reducing the amount of the pressurized fluid can prevent the pressurized fluid from leaking outside of the vacuum air slider 1. Thus, the vacuum pump for discharging the pressurized fluid from the vacuum air slider 1 needs reduced exhaust velocity and electrical power. As a result, the cost for discharging the pressurized fluid can be reduced. Further, reducing the leakage of the pressurized fluid from the static pressure slider can reduce the loss of vacuum in the vacuum chamber (not shown), thereby lowering the exhaust velocity and electrical power necessary for maintaining the degree of vacuum in the vacuum chamber. Thus, the running cost of the static pressure slider is reduced also in this point.

Even if the movable member 3 gets into contact with the stationary member 2, according to the capacitance measured by the measuring portion 70, the contact of the movable member 3 to the stationary member 2 can be immediately detected. As described above, the displacement bodies 31-34 are pressed in the direction apart from the stationary member 2. With such structure, the displacement bodies 31-34 are retracted by the controlling portion 72 so that the problem due to the contact is held to the minimum.

Meanwhile, the distances between the stationary member 2 and the movable member 3 is maintained properly, unnecessarily large gap is not formed between the stationary member 2 and the movable member 3, thereby reducing the leakage of the pressurized fluid into the outside of the vacuum air slider 1. This contributes to reduction in the cost for discharging the pressurized fluid out of the vacuum air slider 1, and for maintaining the vacuum in the vacuum chamber (not shown in drawings).

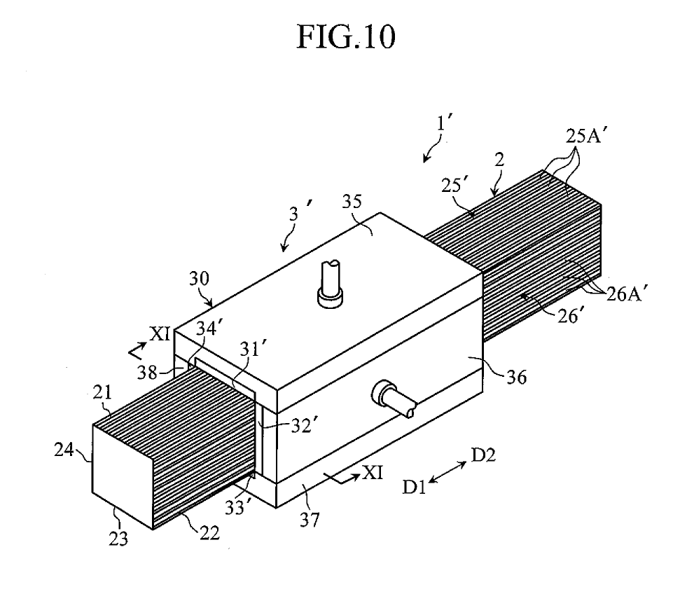

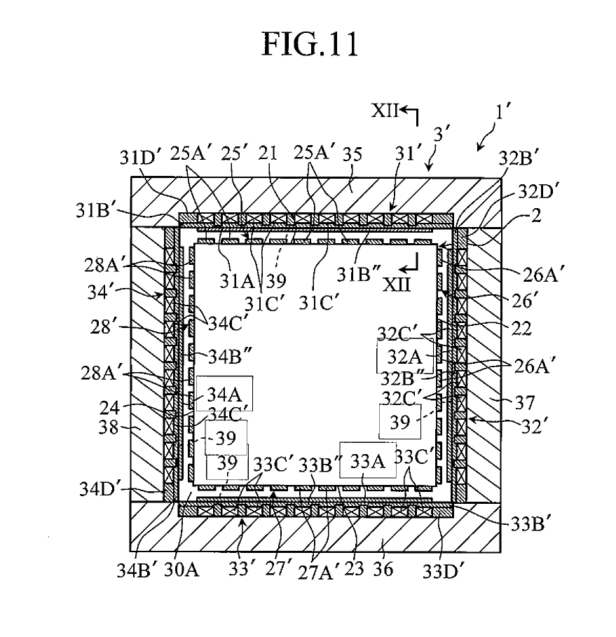

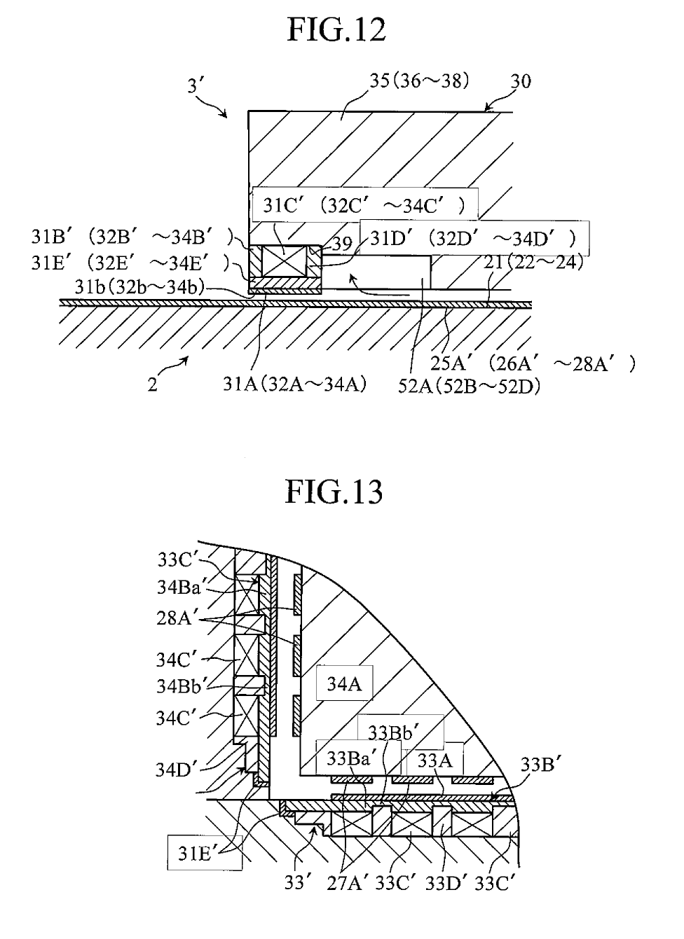

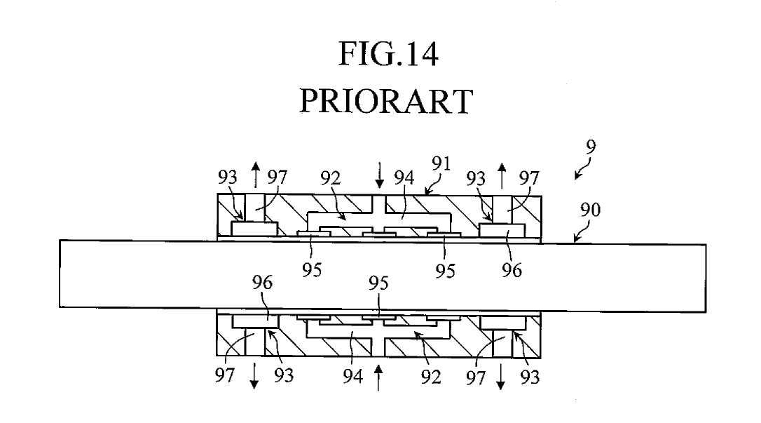

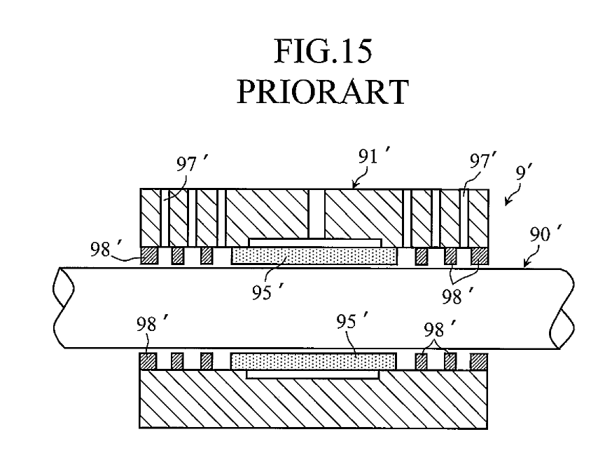

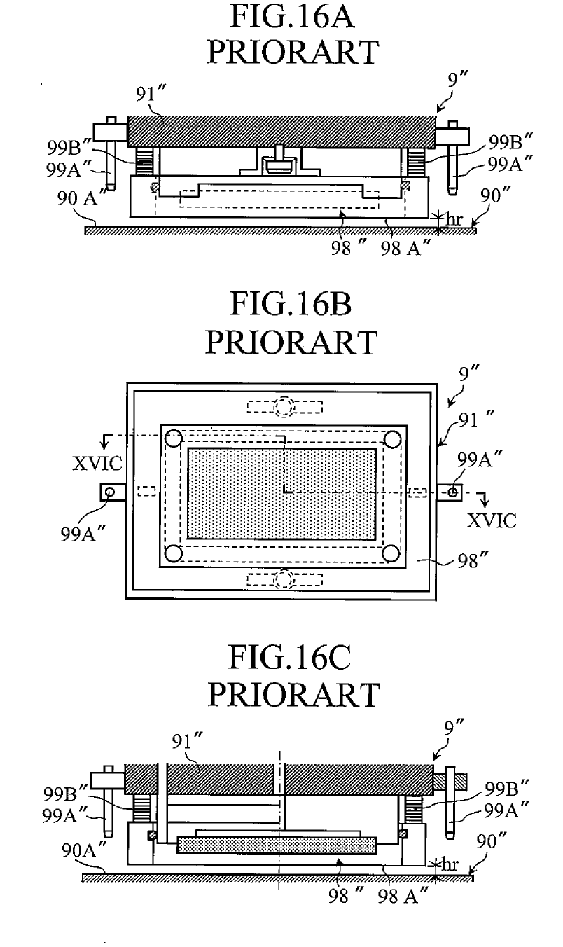

Next, a second embodiment of the present invention is described below with reference to FIGS. 10-13. In these drawings, elements identical to those in the first embodiment, described already with reference to FIGS. 1-9, are given the same reference numbers and duplicated description is omitted.

The vacuum air slider 1′ illustrated in FIGS. 10-13 includes displacement bodies 31′, 32′, 33′ and 34′ and first conductive layers 25′, 26′, 27′ and 28′ which are different from those in the above-described static pressure slider 1 (see FIGS. 1-9).

Each of the displacement bodies 31′-34′ keeps the distances between the end portions of the movable member 3′ and the stationary member 2′ to be relatively small, while preventing the movable member 3′ from getting into contact with the stationary member 2′, and includes respective one of deformable members 31B′, 32B′, 33B′ and 34B′, and a plurality of piezoelectric elements 31C′, 32C′ 33C and 34C′.

The deformable members 31B′-34B′ control the distances between the end portions of the movable member 3′ (the displacement bodies 31′-341) and the stationary member 2, and are made of elastically deformable plates. These deformable members 31B′-34B′ respectively include a plurality of thick portions 31Ba′, 32Ba′, 33Ba′ and 34Ba′ to which the piezoelectric elements 31C′-34C′ are respectively fixed, and a plurality of thin portions 31Bb′, 32Bb′, 33Bb′ and 34Bb′ provided between the adjacent thick portions 31Ba′-34Ba′. The formable members 318-34B′ have resilient property such as a plate spring. The deformable members 31B′-34B′ are fixed to the movable member via bond 31B′ such as epoxy resin, at their ends (see FIG. 13). Such deformable member 31B′-34B′ may be made of a material having toughness such as zirconia, sapphire, and silicon nitride. The bond 31B′ may be provided to the upper and lower surfaces of the piezoelectric elements 31C′-34C′ so that the piezoelectric elements 31C′-34C′ and the deformable members 31B′-34B′ as well as the piezoelectric elements 31C′-34C′ and the boards 35-38 are fixed to each other by the bond 31E′.

The piezoelectric elements 31C′-34C′ serve to elastically deform the deformable members 31B′-34B′, and are fixed to the thick portions 31Ba′-34Ba′ of the deformable members 31B′-34B′ by a bond such as epoxy resin. In other words, the piezoelectric elements 31C′-34C′ are aligned and fixed on the deformable members 31B′-34B′. The piezoelectric elements 31C′-34C′ are individually expanded and contracted by a controlling portion (see FIG. 9). By individually expanding and contracting the piezoelectric elements 31C′-34C′, the deformable members 31B′-34B′ are deformed at any desired portion so that the distances between the end portions of the movable member 3′ (the displacement bodies 31′-34′) and the stationary member 2 is adjusted.

The piezoelectric elements 31C′-34C′ are surrounded by protect resin members 31D′, 32D′, 33D′, 34D′. Such protect resin members 31D′-34D′ may be made of a elastically deformable material such as silicon resin and fluorine resin, which do not prevent the expansion and contraction of the piezoelectric elements 31C′-34C′. Surrounding the piezoelectric elements 31C′-34C′ by the protect resin members 31D′-34D′ can reduce the loss of vacuum and protect the piezoelectric elements 31C′-34C′.

Such displacement bodies 31′-34′ are fixed to the recesses 39 formed at the end portions of the boards 35-38, adjacent to the linear discharge channels 52A-52D, by a bond such as epoxy resin. The displacement bodies 31′-34′, positioned adjacent to the linear discharge channels 52A-52D, protrude beyond the main body 30 of the movable member 3′ slightly (by about 1-10 μm). In this state, the second conductive layers 31A″-34B″ face the guiding surfaces 21-24 (the surfaces of the first conductive layers 25′-28′) of the stationary member 2, substantially parallel thereto. With such structure of the displacement bodies 31′-34′ protruding beyond the main body 30 of the movable member 3, the pressurized fluid can be prevented from leaking out of the movable member 3, and the pressurized fluid can be properly guided to the linear discharge channels 52A-52D. In a case that the linear discharge channels 52A-52D are positioned at the middle portion of the main body 30 of the movable member 3, the displacement bodies 31′-34′ may be also positioned in the vicinity of the linear discharge channels 52A-52D, and preferably positioned on a side of the end portion adjacent to the linear discharge channels 52A-52D.

First conductive layers 25′-28′ are used for measuring the distances between the end portions of the movable member 3 (the displacement bodies 31′-35′) and the stationary member 2, and respectively include a plurality of individual electrodes 25A′, 26A′, 27A′ and 28A′. The individual electrodes 25A′ 26A′, 27A′ and 28A′ are positioned to respectively face the piezoelectric elements 31C′-34C′, and extend in the axial direction of the stationary member 2.

In such vacuum air slider 1′, individual measurements of the capacitances between each of the individual electrodes 25A′-28A′ and the respective one of the second conductive layers 31A-34A is individually measured. In this way, the actual distances between the stationary member 2 and the movable member 3 can be measured at each of the piezoelectric elements 31C′-34C′. Such measured capacitance (distance) is processed in a controlling portion (see FIG. 9) so that the piezoelectric elements 31C′-34C′ are individually controlled to expand and contract. Since the piezoelectric elements 31C′-34C′ are fixed to the thick portions of the deformable members 31B′-34B′ which are elastically deformable, the distances to the stationary member 2 are controlled individually at a plurality of portions of each of the displacement bodies 31′-34′. As a result, in the vacuum air slider 1′, the distances between the displacement bodies 31′-34′ and the stationary member 2 are delicately adjusted in the direction perpendicular to the moving directions D1 and D2 of the movable member 3, whereby the distances in the perpendicular direction are kept to be uniform.

In the vacuum air slider 1′, alternatively or additionally to the plurality of individual electrodes 25A′-28A′ of the first conductive layers 25′-28′, the second conductive layers 31A-34A may include a plurality of individual electrodes.

Further, in the vacuum air slider 1′, the deformable members 31B′-34B′ may be conductive, to have the function of the second conductive layers 31A-34A. In this case, the deformable members 31B′-34B′ are made of a metal such as copper and titanium, or a conductive ceramics material such as silicon carbide, Al₂O₃—TiC (AlTiC: a composite material of alumina and titanium carbide), and cermet, for example.

The static pressure slider according to the present invention is not limited to the above-described embodiments, and may be variously modified. For example, the means for measuring the distances between the stationary member and the movable member are not necessarily incorporated in the slider, if at least capable of measuring the actual distances. The measuring portion may be provided separately from the stationary member and the movable member, and a known displacement gauge may be integrally provided to the movable member. Examples of the displacement gauge include a capacitance type displacement gauge, an eddy current displacement gauge, and an optical displacement gauge utilizing an optical method such as optical pickup.

Further, the displacement bodies may be omitted and the whole movable member may be displaced relative to the stationary member.

The present invention is not limited to be applied to the above-described static pressure slider, but may also be applied to other types of static pressure sliders. For example, the present invention may be applied to a static pressure slider with a cylindrical stationary member and a tubular movable member, as well as to a simple static pressure slider with a levitated flat movable member.

1. A static pressure slider comprising:
a stationary member including a guiding surface; and
a movable member configured to be movable relative to the stationary member along the guiding surface under a condition that a static pressure fluid layer formed of a pressurized fluid is provided between the stationary member and the guide surface;
wherein the static pressure slider further comprises a measuring unit adapted for measuring an actual distance between the guiding surface and an facing surface of the movable member which faces the guide surface and is located at an end portion of the movable member.

2. The static pressure slider according to claim 1, wherein the measuring unit is adapted for measuring a capacitance between the guiding surface and the facing surface.

3. The static pressure slider according to claim 2, wherein the measuring unit comprises a first conductive layer formed on the guiding surface and a second conductive layer formed on the facing surface, the first and second conductive layers being configured to be used for measuring the capacitance therebetween.

4. The static pressure slider according to claim 3, wherein each of the first and second conductive layers has a smooth surface with the maximum height Rz of not more than 1 μm.

5. The static pressure slider according to claim 3, wherein each of the first and second conductive layers is made of a metal or a single crystal.

6. The static pressure slider according to claim 5, wherein each of the first and second conductive layers comprises a thick layer formed of a metal.

7. The static pressure slider according to claim 3, wherein each of the first and second conductive layers has a thickness of not less than 0.1 μm and not more than 0.1 mm.

8. The static pressure slider according to claim 3, wherein each of the first and second conductive layers is made of a non-magnetic material.

9. The static pressure slider according to claim 1, wherein the movable member comprises a main body and a displacement body configured to be displaceable relative to the body in a direction perpendicular to the moving direction of the movable member, the displacement body having an end surface including the facing surface of the movable member,
wherein the static pressure slider further comprises a controller configured to control the position of the displacement body in order to adjust the distance between the guiding surface and the facing surface based on the measurement result obtained by using the measuring unit.

10. The static pressure slider according to claim 9, wherein the movable member further comprises a piezoelectric element for moving the displacement body, and
wherein the piezoelectric element is controlled to expand and contract by the controller.

11. The static pressure slider according to claim 9, wherein the displacement body is supported by the main body while the displacement body is pressed in a direction apart from the guiding surface.

12. The static pressure slider according to claim 9, further comprising a sealing member for sealing a gap between the main body and the displacement body.

13. The static pressure slider according to claim 12, wherein the sealing member is compressed by the displacement body.

14. The static pressure slider according to claim 9, wherein the main body comprises a discharge channel for discharging the pressurized fluid outside, and wherein the displacement body is positioned at an end portion thereof adjacent to the discharge channel.

15. The static pressure slider according to claim 9, wherein the displacement body comprises a plurality of piezoelectric elements aligned in a direction perpendicular to the moving direction of the movable member.

16. The static pressure slider according to claim 15, wherein the displacement body comprises an elastically deformable member to which the piezoelectric elements is fixed.

17. The static pressure slider according to claim 16, wherein the deformable member comprises a plurality of thick portions to which the piezoelectric elements are fixed, and a plurality of thin portions positioned between the adjacent thick portions.

18. The static pressure slider according to claim 15, wherein the displacement body further comprises a protect resin member surrounding the piezoelectric elements.

19. The static pressure slider according to claim 15, wherein the measuring unit comprises a first conductive layer formed on the guiding surface and a second conductive layer formed on the facing surface, wherein at least one of the first and second conductive layers includes a plurality of individual electrodes formed in a region corresponding to the piezoelectric elements, and
wherein the measuring unit is configured to be used for measuring a capacitance between the first and second conductive layers by utilizing the individual electrodes.
